(19) United States
(12) Patent Application Publication
(10) Pub. No.: US 2013/0154017 A1
(43) Pub. Date: Jun. 20, 2013

(54) Self-Aligned Gate Structure for Field Effect Transistor

(71) Applicant: Microchip Technology Incorporated, Chandler, AZ (US)

(72) Inventors: Gregory Dix, Tempe, AZ (US); Harold Kline, Phoenix, AZ (US); Rodney Schroeder, Phoenix, AZ (US); Daniel J. Grimm, Mesa, AZ (US)

(73) Assignee: MICROCHIP TECHNOLOGY INCORPORATED, Chandler, AZ (US)

(21) Appl. No.: 13/709,342

(22) Filed: Dec. 10, 2012

Related U.S. Application Data
(60) Provisional application No. 61/570,395, filed on Dec. 14, 2011.

(51) Int. Cl. H01L 27/088; H01L 29/66

(52) U.S. Cl. CPC H01L 27/088; H01L 29/66477
USPC 257/368; 438/299

(57) ABSTRACT

A field effect transistor has a substrate with an epitaxial layer, base regions extending from a top of the epitaxial layer into the epitaxial layer, an insulation region having side walls and extending between two base regions on top of the substrate; and a polysilicon gate structure covering the insulation region including the side walls, wherein effective gates are formed by a portion of the polysilicon covering side walls above the base region.

### CROSS-REFERENCE TO RELATED APPLICATIONS

This application claims the benefit of U.S. Provisional Application No. 61/570,395 filed on Dec. 14, 2011, entitled “SELF-ALIGNED GATE STRUCTURE FOR FIELD EFFECT TRANSISTOR”, which is incorporated herein in its entirety.

### TECHNICAL FIELD

The present disclosure relates field effect transistors, in particular the gate structure and method for forming such a gate as a self aligned gate.

### BACKGROUND

Power metal oxide semiconductor field-effect transistors (MOSFET) are generally used to handle high power levels in comparison to lateral transistors in integrated circuits. FIG. 9 shows a typical MOSFET which uses a vertical diffused MOSFET structure, also called double-diffused MOSFET structure (DMOS or VDMOS).

As shown, for example, in FIG. 9, on an N⁺ substrate 915 there is a N⁻ epitaxial layer formed whose thickness and doping generally determines the voltage rating of the device. From the top into the epitaxial layer 910 there are formed N⁺ doped left and right source regions 930 surrounded by P-doped region 920 which forms the P-base. The P-base may have an out diffusion area 925 surrounding the P-base 920. A source contact 960 generally contacts both regions 930 and 920 on the surface of the die and is generally formed by a metal layer that connects both left and right source region. An insulating layer 950, typically silicon dioxide or any other suitable material, insulates a polysilicon gate 940 which covers a part of the P-base region 920 and out diffusion area 925. The gate 940 is connected to a gate contact 970 which is usually formed by another metal layer. The bottom side of this vertical transistor has another metal layer 905 forming the drain contact 980. In summary, FIG. 9 shows a typical elementary cell of a MOSFET that can be very small and comprises a common drain, a common gate and two source regions and two channels. Other similar cells may be used in a vertical power MOS-FET. A plurality of such cells may generally be connected in parallel to form a power MOSFET.

In the On-state, a channel is formed within the area of regions 920 and 925 covered by the gate reaching from the surface into the regions 920 and 925, respectively. Thus, current can flow as indicated by the horizontal arrow into the drain region which basically extends from the top of the epitaxial layer 910 between the two regions 925 down to the substrate 915. The cell structure must provide for a sufficient width d of gate 940 to allow for this current to turn into a vertical current flowing to the drain side as indicated by the vertical arrows.

Such structures have a relatively high gate capacitance, in particular gate-drain capacitance due to the overall structure of the device. To reduce the drain capacity a split gate may be provided as disclosed in co-pending U.S. application Ser. No. 13/288,181, “Vertical DMOS-FIELD EFFECT TRANSISTOR” by Gregory Dix et al. which is hereby incorporated by reference. However even such a structure may have a two gates over the channels which still overlap the drain to contribute to a significant gate-drain capacitance.

### SUMMARY

According to an embodiment, a method for manufacturing a field effect transistor may comprise providing a stack comprising a substrate and epitaxial layer deposited on the substrate, a multilayer insulating layer on top of the epitaxial layer, and a first gate-layer on top of the insulating layer; patterning the stack to provide openings up to a lowest layer of the multi-layer insulating layer; implanting base regions; depositing a second gate layer covering the openings and the first gate layer; and performing an etching up to the lowest layer of the multi-layer insulating layer such that spacers on sides of the openings remain and form respective gate structures of the field effect transistor.

According to a further embodiment, the multi-layer insulating layer may comprise a first oxide layer on top of the substrate, a nitride layer on top of the first oxide layer; a second oxide layer on top of the nitride layer. According to a further embodiment, the first layer can be a Gate oxide. According to a further embodiment, each layer of the multi-layer insulating layer may have a different thickness. According to a further embodiment, the Gate oxide layer may have a thickness of approximately 250 Å, the nitride layer of approximately 400 Å, the thick oxide layer of approximately 2500 Å, and the first polysilicon layer of approximately 1500 Å. According to a further embodiment, the second polysilicon layer may have a thickness of approximately 2500 Å. According to a further embodiment, the two adjacent gate structures in adjacent openings can be bridged by the first polysilicon layer. According to a further embodiment, the method may further comprise the step of forming self-aligned source regions within the base regions. According to a further embodiment, the thickness of the multi-layer insulating layer can be chosen such that a capacitance between the first polysilicon layer and a drain region is minimized.

According to another embodiment, a field effect transistor may comprise a substrate comprising an epitaxial layer; base regions extending from a top of the epitaxial layer into the epitaxial layer; an insulation region having side walls and extending between two base regions on top of the substrate; and a polysilicon gate structure covering the insulation region including the side walls, wherein effective gates are formed by a portion of the polysilicon covering side walls above the base region.

According to a further embodiment of the field effect transistor, the insulation region may comprise a multi-layer insulating structure comprising: a first oxide layer on top of the epitaxial layer, a nitride layer on top of the first oxide layer, a second oxide layer on top of the nitride layer. According to a further embodiment of the field effect transistor, the polysilicon gate structure may comprise a first and a second polysilicon layer, wherein the first polysilicon layer covers the insulation region and the second layer includes spacers covering the side walls and forming the effective gates. According to a further embodiment of the field effect transistor, the first layer can be a Gate oxide. According to a further embodiment of the field effect transistor, each layer of the multi-layer insulation structure may have a different thickness. According to a further embodiment of the field effect transistor, the Gate oxide layer may have a thickness of approximately 250 Å, the nitride layer of approximately 400 Å, the thick oxide layer of approximately 2500 Å, and the first polysilicon layer of approximately 1500 Å. According to a further embodiment of the field effect transistor, the second polysilicon layer may have a thickness of approximately 2500 Å. According to a further embodiment of the field effect transistor, the two adjacent gate structures in adjacent openings can be bridged by a polysilicon layer. According to a further embodiment of the field effect transistor, the field effect transistor may further comprise self-aligned source regions within the base regions. According to a further embodiment of the field effect transistor, the thickness of the multi-layer insulation structure can be chosen such that a capacitance between the first polysilicon layer and a drain region is minimized. According to a further embodiment of the field effect transistor, a drain region can be formed under the insulation region.

### BRIEF DESCRIPTION OF THE DRAWINGS

FIG. 1 shows the basic structure of a conventional vertical DMOS transistor;

FIGS. 2-7 show various steps for manufacturing an improved vertical DMOS transistor according to various embodiments;

FIG. 8 show sectional views of actual embodiments;

FIGS. 9 and 10 show a conventional vertical DMOS transistor.

### DETAILED DESCRIPTION

Therefore a need exists, for a field effect transistor with a reduce gate-to-drain capacitance to improve device performance. According to various embodiments, a gate for Power FET products can be created that will reduce the gate-to-drain capacitance by using a spacer type etch to define a self aligned gate. The device according to various embodiments, is similar in function to a STD Power FET, however the gate only covers the thin oxide area of the channel (p-base) and the poly that is over the Drain area has a much thicker oxide thus reducing the capacitance.

The following discusses a method for forming a spacer gate to reduce gate-to-drain capacitance for FET devices. By reducing the Gate length to only cover the channel portion of the device the unnecessary capacitance is reduced without the need for advanced lithography. This also eliminates critical alignment requirements in the fabrication process.

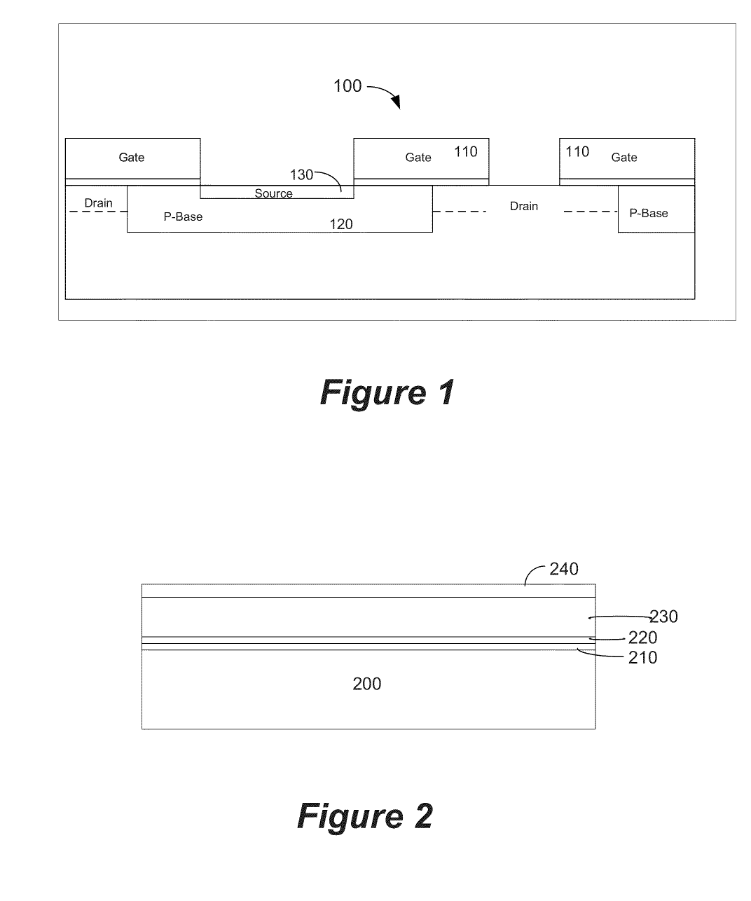

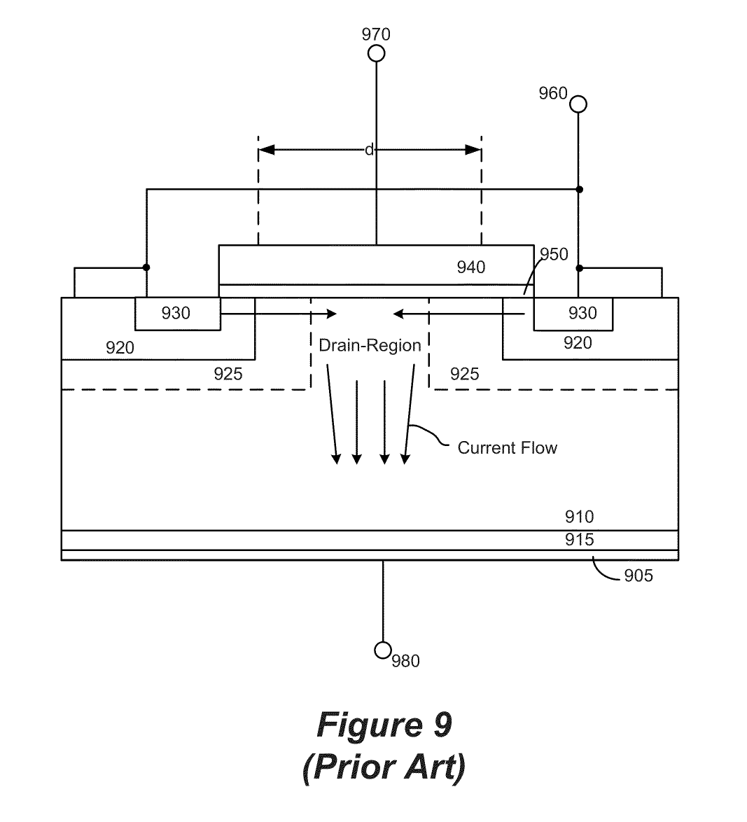

FIG. 1 shows that in a conventional transistor as discussed with respect to FIG. 9, the current structure has a significant portion of the gate overlapping the drain. One solution that can be used is to split the poly gate over the drain as shown in FIG. 1 to reduce capacitance to the drain as discussed in pending U.S. application Ser. No. 13/288,181, “Vertical DMOS-FIELD EFFECT TRANSISTOR” by Gregory Dix et al. which is hereby incorporated by reference.

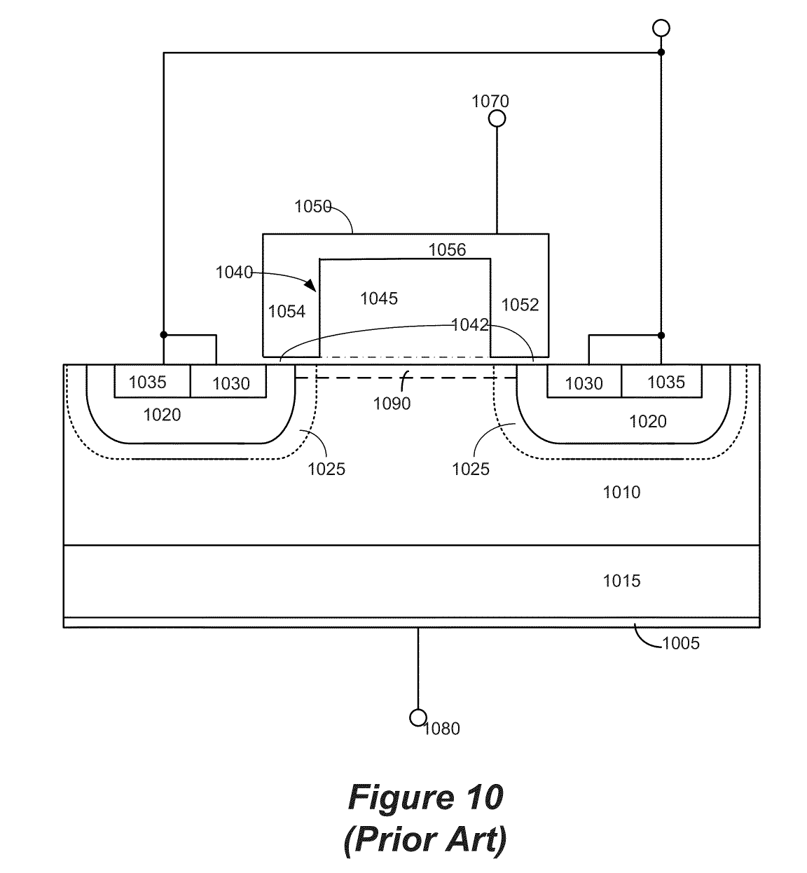

FIG. 10 shows yet another conventional embodiment that can be used to reduce the gate drain capacitance according to co-pending U.S. application Ser. No. 13/291,344, filed Nov. 8, 2011, with the title “Vertical DMOS-FIELD EFFECT TRANSISTOR” by Rohan S. Braithwaite, et al. which is hereby incorporated by reference. In FIG. 10 a cross-sectional view of an improved conventional vertical DMOS-FET is depicted. A highly doped N⁺ substrate 1015 is provided on top of which an N⁻ epitaxial layer 1010 has been grown. From the top into the epitaxial layer 1010 there are formed N⁺ doped left and right source regions 1030 each surrounded by a P-doped region 1020 which forms the P-base. A heavier doped P+ region 1035 can be implanted within the P-base 1020 for connection to the source terminal. Each P-base 1020 may additionally be surrounded by an associated out diffusion area 1025 as indicated by the dotted line. Other structures for the left and right source regions 1030 may be used. Similar as for the transistor shown in FIG. 9, a source contact 1060 generally contacts both regions 1030 and 1020 on the surface of the die and is generally formed by a metal layer that connects both left and right source region. An insulating structure 1040 is used to insulate a left and right gates 1052, 1054. This structure 1040 comprises a gate oxide layer 1042 under polysilicon gate 1052, 1054 of the transistor as indicated by the dash-dotted line. This gate oxide layer 1042 can be formed using a deposited oxide which is followed up by a thermal oxidation which densifies the deposited oxide 1042 making it more robust. However, such a structure uses rather complex manufacturing steps including trench etching for the two gates 1052 and 1054 and may still suffer from a gate-drain overlap.

FIGS. 2-8 show various process steps of an embodiment of an improved structure accomplishing a vertical power MOSFET transistor with a reduced gate-drain capacitance and self alignment features. Starting with a conventional Epi & Well structure, a “Stack” is formed according to various embodiments on an epi-layer 200 with the following layers: a thin Gate oxide (Tox) layer 210, e.g. 250 Å or any other appropriate gate insulating layer, a nitride layer 220, e.g. 400 Å, a thick oxide layer 230, e.g. 2500 Å, and a first polysilicon layer 240, e.g. 1500 Å. Other insulating layers within the insulating structure may be used to provide a sufficiently high stack. The thickness (height) of the stack provides for reduction in Gate-drain capacitance as will be explained in more detail below. Hence, the multi-layer insulation structure may have a plurality of different layers that provide for the same insulating feature.

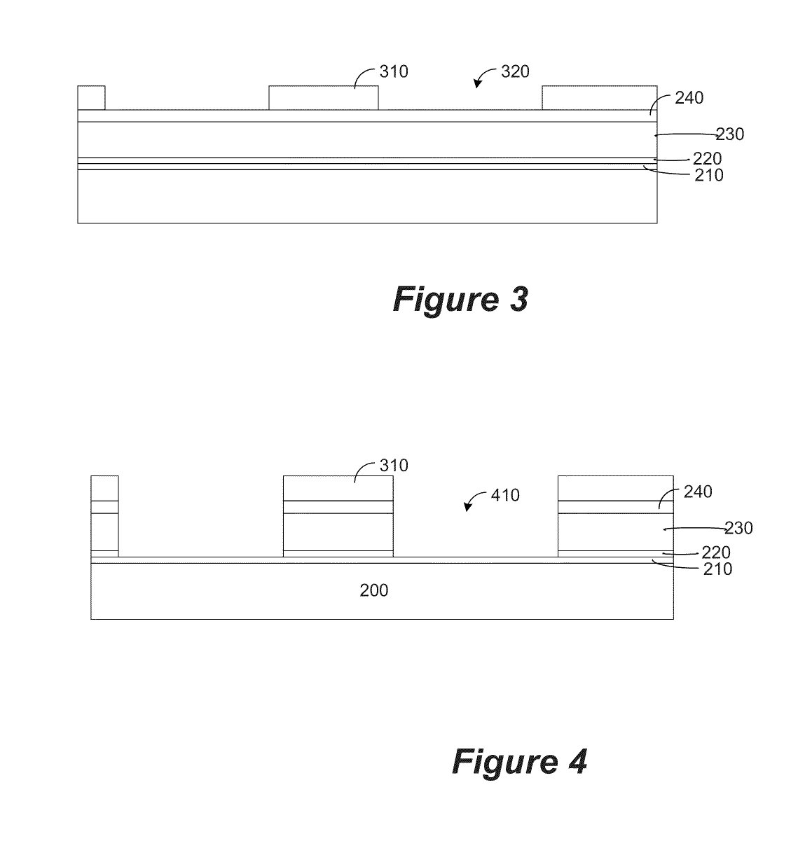

FIG. 3 shows the stack of FIG. 2 after a masking step with masking layer 310 has been applied to define the base region of the device. To this end, the masking layer 310 provides for openings 320 to allow etching of the underlying regions. FIG. 3 shows thus the remaining photo mask 310 on top of the stack.

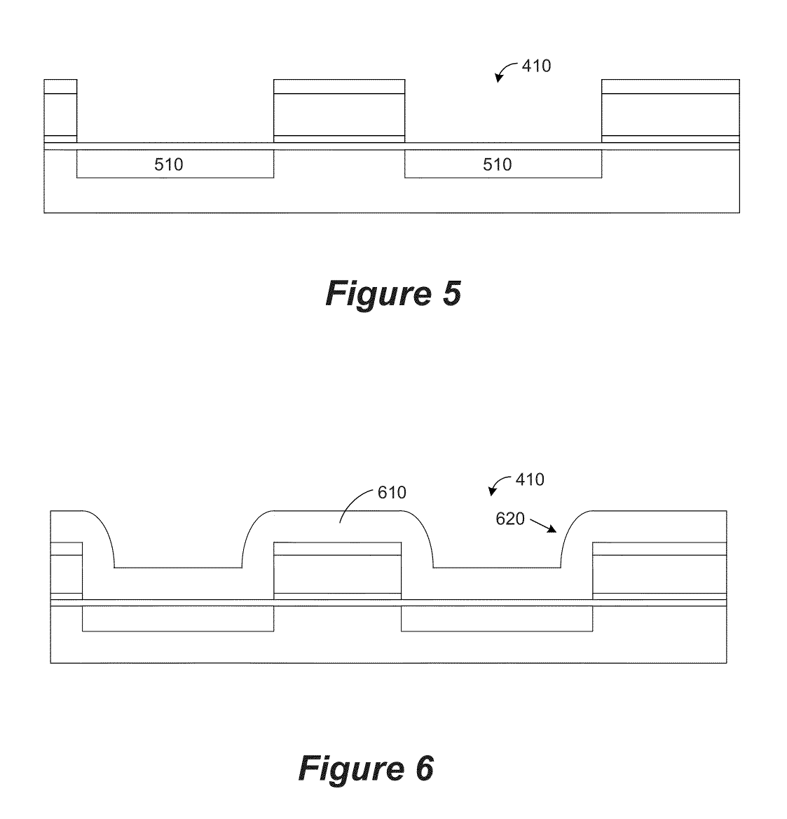

FIG. 4 shows the stack of FIG. 3 after the poly, oxide and nitride layers 220, 230, 240 have been etched leaving the Gate oxide layer 210 intact. Thus, the removed different layers 220, 230, 240 in openings 410 now allow for implanting the base regions. FIG. 5 shows the stack after the P-base 510 has been implanted.

FIG. 6 shows the device after a second layer of polysilicon 620 has been deposited, e.g. with a thickness of 2500 Å. As can be seen this deposition also covers the side walls 620 of the openings 410. This additional cover of the sides and its structure may be provided through the depth of opening 410. The deposition of polysilicon thus causes a rounding of the edges of openings 410 as can be seen in FIG. 6. Thus, a thicker deposition with respect to the vertical direction in the bottom edge area of openings 410 occurs.

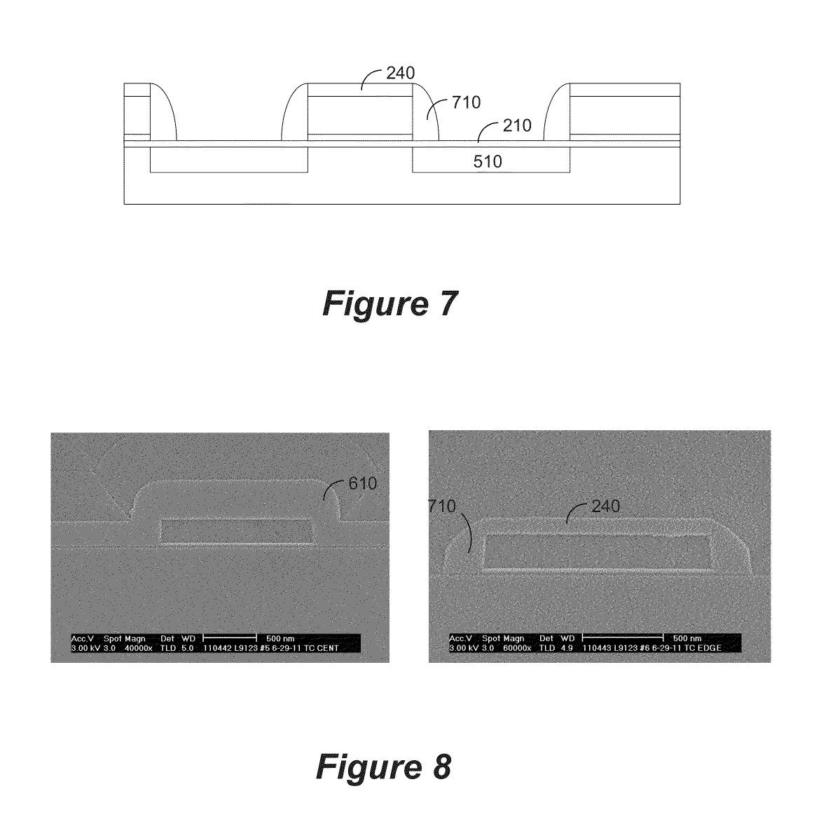

FIG. 7 shows the device of FIG. 6 after a poly “spacer’ type etching has been performed partially removing the second poly 610 on top of Tox layer 210 and on top of the first poly layer 240 but leaving specific side spacers 710 formed by the deposition of the second poly layer 610. The spacers 710 remain as the etching has its strongest effect in the vertical direction. Source regions can thereafter be implanted in the P-base 510 as known in the art. A bridged gate structure is formed by this process wherein only the portion of the gate formed by the “spacer” 710 covers the P-base and thereby will act as gates and can form the channel when appropriate voltages are applied. The portion of the gate 240 formed by the top layer is spaced apart from the drain far enough to significantly reduce the gate-to-drain capacitance.

FIG. 8 shows cross section views of an actual real device according to various embodiments wherein the left side shows the cross section after the second poly deposition (see FIG. 6) and the right side after the poly “spacer” etching as discussed above (See FIG. 7).

The devices manufactured according to various embodiments, provide for a lower gate-to-drain capacitance (Lower FOM) wherein the Poly-gate is self aligned to cover just the P-Base. This allows tighter Pitch of gates as there is no need for an angled P-Base implant to get the P-Base under the Poly as necessary in conventional devices.

What is claimed is:

1. A method for manufacturing a field effect transistor comprising:
providing a stack comprising a substrate and epitaxial layer deposited on said substrate, a multilayer insulating layer on top of the epitaxial layer, and a first gate-layer on top of the insulating layer;
patterning the stack to provide openings up to a lowest layer of the multi-layer insulating layer;
implanting base regions;
depositing a second gate layer covering the openings and the first gate layer;
performing an etching up to the lowest layer of the multi-layer insulating layer such that spacers on sides of the openings remain and form respective gate structures of the field effect transistor.

2. The method according to claim 1, wherein the multi-layer insulating layer comprises a first oxide layer on top of the substrate, a nitride layer on top of the first oxide layer; a second oxide layer on top of the nitride layer.

3. The method according to claim 2, wherein the first layer is a Gate oxide.

4. The method according to claim 1, wherein each layer of the multi-layer insulating layer has a different thickness.

5. The method according to claim 2, wherein the Gate oxide layer has a thickness of approximately 250 Å, the nitride layer of approximately 400 Å, the thick oxide layer of approximately 2500 Å, and the first polysilicon layer of approximately 1500 Å.

6. The method according to claim 1, wherein the second polysilicon layer has a thickness of approximately 2500 Å.

7. The method according to claim 1, wherein the two adjacent gate structures in adjacent openings are bridged by said first polysilicon layer.

8. The method according to claim 1, further comprising the step of forming self-aligned source regions within the base regions.

9. The method according to claim 1, wherein the thickness of the multi-layer insulating layer is chosen such that a capacitance between the first polysilicon layer and a drain region is minimized.

10. A field effect transistor comprising:
a substrate comprising an epitaxial layer;
Base regions extending from a top of the epitaxial layer into the epitaxial layer;
an insulation region having side walls and extending between two base regions on top of the substrate;
a polysilicon gate structure covering said insulation region including said side walls, wherein effective gates are formed by a portion of the polysilicon covering side walls above said base region.

11. The field effect transistor according to claim 10, wherein the insulation region comprises a multi-layer insulating structure comprising: a first oxide layer on top of the epitaxial layer, a nitride layer on top of the first oxide layer, a second oxide layer on top of the nitride layer.

12. The field effect transistor according to claim 10, wherein the polysilicon gate structure comprises a first and a second polysilicon layer, wherein the first polysilicon layer covers the insulation region and the second layer includes spacers covering said side walls and forming said effective gates.

13. The field effect transistor according to claim 11, wherein the first layer is a Gate oxide.

14. The field effect transistor according to claim 11, wherein each layer of the multi-layer insulation structure has a different thickness.

15. The field effect transistor according to claim 13, wherein the Gate oxide layer has a thickness of approximately 250 Å, the nitride layer of approximately 400 Å, the thick oxide layer of approximately 2500 Å, and the first polysilicon layer of approximately 1500 Å.

16. The field effect transistor according to claim 12, wherein the second polysilicon layer has a thickness of approximately 2500 Å.

17. The field effect transistor according to claim 10, wherein the two adjacent gate structures in adjacent openings are bridged by a polysilicon layer.

18. The field effect transistor according to claim 10, further comprising self-aligned source regions within the base regions.

19. The field effect transistor according to claim 12, wherein the thickness of the multi-layer insulation structure is chosen such that a capacitance between the first polysilicon layer and a drain region is minimized.

20. The field effect transistor according to claim 10, wherein a drain region is formed under said insulation region.
